(19) United States
(12) Patent Application Publication
(10) Pub. No.: US 2025/0331363 A1
(43) Pub. Date: Oct. 23, 2025

(54) DISPLAY DEVICE AND METHOD OF MANUFACTURING THE SAME

(71) Applicant: Samsung Display Co., LTD., Yongin-si (KR)

(72) Inventors: Sang Gyun KIM, Yongin-si (KR); Dong Chan KIM, Yongin-si (KR); Byung Seok LEE, Yongin-si (KR)

(21) Appl. No.: 18/924,012

(22) Filed: Oct. 23, 2024

(30) Foreign Application Priority Data
Apr. 17, 2024 (KR) 10-2024-0051069

(51) Int. Cl. H10K 59/122; H10K 59/12

(52) U.S. Cl. CPC H10K 59/122; H10K 59/1201

(57) ABSTRACT

A display device includes a light emitting element layer including: a planarization layer; an anode electrode on the planarization layer; a pixel defining layer on the anode electrode; a trench penetrating the pixel defining layer and defined in the planarization layer; a light emitting structure over first and second sub-pixels, and on the anode electrode exposed by the pixel defining layer, the light emitting structure including a first light emitting structure forming the first sub-pixel and a second light emitting structure forming the second sub-pixel; an intermediate light emitting structure within the trench at a boundary area and including the same material as the light emitting structure; an intermediate connection layer in the boundary area and connecting the first light emitting structure and the second light emitting structure. The intermediate light emitting structure and the intermediate connection layer are physically spaced apart from each other.

This application claims priority to Korean Patent Application No. 10-2024-0051069, filed on Apr. 17, 2024, and all the benefits accruing therefrom under 35 U.S.C. § 119, the content of which in its entirety is herein incorporated by reference.

### BACKGROUND

### Field

The present disclosure relates to a display device and a method of manufacturing the same.

### Discussion

In recent years, as interest in information display is increasing, research and development on display devices are continuously conducted.

A display device may include sub-pixels each including an organic light emitting diode (“OLED”). The organic light emitting diode is an active light-emitting type display element and have the advantages of not only having a wide viewing angle and high contrast, but also being able to be driven at low voltage, being lightweight and thin, and having a fast response speed.

The organic light emitting diode may be included in each sub-pixel and may include a hole transport unit, an electron transport unit, and a light emitting layer between the hole transport unit and the electron transport unit. Excitons may be generated when holes provided from the hole transport unit and electrons provided from the electron transport unit recombine in the light emitting layer. Light may be generated as the generated excitons transition from an excited state to a ground state.

The organic light emitting diode may include a cathode electrode configured to provide electrons to emit light. The cathode electrode may be composed of a common electrode of the sub-pixels. The cathode electrode needs to be appropriately patterned throughout areas where the sub-pixels are formed so that an appropriate cathode signal is supplied to each organic light emitting diode.

Electrical signals supplied to adjacent sub-pixels need to be distinguished from each other. For example, there may be a risk that electrical signals interfere with each other due to leakage current (lateral leakage) occurring between the sub-pixels. Accordingly, a display device that can reduce the risk of leakage current is desirable.

### SUMMARY

An aspect of the present disclosure is to provide a display device in which the risk of leakage current can be reduced, and a method of manufacturing the same.

Another aspect of the present disclosure is to provide a display device capable of having high resolution and excellent display quality, and a method of manufacturing the same.

Another aspect of the present disclosure is to provide a display device that can secure a process margin, and a method of manufacturing the same.

According to embodiments of the present disclosure, a display device including sub-pixels including a first sub-pixel and a second sub-pixel adjacent to each other includes: a pixel circuit layer including a pixel circuit on a substrate; and a light emitting element layer disposed on the pixel circuit layer. The light emitting element layer includes a planarization layer; an anode electrode disposed on the planarization layer; a pixel defining layer, at least a portion of which is disposed on the anode electrode; a trench penetrating the pixel defining layer and defined in at least a portion of the planarization layer; a light emitting structure disposed over the first sub-pixel and the second sub-pixel, and at least a portion of which is disposed on a portion of the anode electrode exposed by the pixel defining layer, where the light emitting structure includes a first light emitting structure forming the first sub-pixel and a second light emitting structure forming the second sub-pixel; an intermediate light emitting structure disposed within the trench at a boundary area between the anode electrode of the first sub-pixel and the anode electrode of the second sub-pixel and including the same material as the light emitting structure; an intermediate connection layer disposed in the boundary area between the first sub-pixel and the second sub-pixel and connecting the first light emitting structure and the second light emitting structure; and a cathode electrode disposed across the first sub-pixel and the second sub-pixel, and at least a portion of which is disposed on the intermediate connection layer. The intermediate light emitting structure and the intermediate connection layer are physically spaced apart from each other.

According to an embodiment, a void may be formed between the intermediate light emitting structure and the intermediate connection layer.

According to an embodiment, the intermediate light emitting structure may be provided in plurality. The trench may be provided in plurality. The number of the plurality of intermediate light emitting structures and the number of the plurality of trenches may be the same.

According to an embodiment, the intermediate connection layer may be provided in plurality. The plurality of intermediate connection layers may be disposed to be spaced apart from each other at edges of the sub-pixels.

According to an embodiment, each of the sub-pixels may have a polygonal shape in a plan view. The plurality of intermediate connection layers may be disposed at vertices of the polygonal shape.

According to an embodiment, a width of a portion of the pixel defining layer between adjacent emission areas may be 0.5 micrometers (μm) to 3.5 μm.

According to an embodiment, the light emitting structure may include a common layer commonly included in each of the first sub-pixel and the second sub-pixel. The common layer may be discontinued by the trench.

According to an embodiment, a thickness of the trench may be greater than half a thickness of the light emitting structure. A width of the trench may be greater than ¼ of the thickness of the light emitting structure.

According to an embodiment, a side surface of the trench may form an included angle of 60 to 90 degrees with respect to a plane on which a major surface of the substrate is disposed.

According to an embodiment, the display device may further include a capping layer disposed across the first sub-pixel and the second sub-pixel and disposed on the cathode electrode; and an encapsulation layer disposed on the capping layer. The capping layer and the encapsulation layer may overlap the intermediate connection layer and the intermediate light emitting structure in a plan view.

According to an embodiment, the capping layer and the intermediate connection layer may be directly adjacent to each other.

According to an embodiment, the intermediate connection layer may include an organic material having electron transport properties.

According to an embodiment, the substrate may include a silicon substrate.

According to embodiments of the present disclosure, a method of manufacturing a display device including sub-pixels including a first sub-pixel and a second sub-pixel adjacent to each other is provided. The method includes: forming a pixel circuit layer including a pixel circuit on a substrate; and forming a light emitting element layer on the pixel circuit layer. The forming of the light emitting element layer includes: forming a planarization layer; forming an anode electrode on the planarization layer; forming a pixel defining layer, at least a portion of which covers the anode electrode; forming a trench penetrating the pixel defining layer and defined in at least a portion of the planarization layer; forming a light emitting structure over the first sub-pixel and the second sub-pixel; forming an intermediate connection layer disposed in a boundary area between the anode electrode of the first sub-pixel and the anode electrode of the second sub-pixel; and forming a cathode electrode over the first sub-pixel and the second sub-pixel. The forming of the intermediate connection layer includes patterning the intermediate connection layer using a fine silicon mask.

According to an embodiment, in the forming of the light emitting structure, at least a portion of the light emitting structure may be discontinued by the trench.

According to an embodiment, the forming of the light emitting structure may include forming an intermediate light emitting structure disposed within the trench.

According to an embodiment, the light emitting structure may include a first light emitting structure forming the first sub-pixel and a second light emitting structure forming the second sub-pixel. The forming of the intermediate connection layer may include: patterning the intermediate connection layer to overlap the intermediate light emitting structure in a plan view; and connecting the first light emitting structure and the second light emitting structure by the intermediate connection layer.

According to an embodiment, the fine silicon mask may define a deposition opening therein. A width of the deposition opening may be 0.2 μm to 0.8 μm.

According to an embodiment, the patterning of the intermediate connection layer may include patterning a plurality of intermediate connection layers. The plurality of intermediate connection layers may be patterned simultaneously.

According to an embodiment, the patterning of the intermediate connection layer may include patterning a plurality of intermediate connection layers. Some of the plurality of intermediate connection layers may be patterned in a first time period, and other intermediate connection layers of the plurality of intermediate connection layers may be patterned in a second time period after the first time period.

### BRIEF DESCRIPTION OF THE DRAWINGS

The accompanying drawings, which are included to provide a further understanding of the invention and are incorporated in and constitute a part of this specification, illustrate embodiments of the inventions, and, together with the description, serve to explain principles of the inventions.

FIG. 1 is a plan view schematically illustrating a display device according to an embodiment.

FIG. 2 is an exploded perspective view schematically illustrating a portion of a display panel of FIG. 1.

FIG. 3 is a plan view schematically illustrating a pixel according to an embodiment.

FIGS. 4 and 5 are plan views schematically illustrating the pixel according to other embodiments.

FIG. 6 is a plan view schematically illustrating a pixel according to another embodiment.

FIG. 7 is a plan view schematically illustrating a pixel according to still another embodiment.

FIG. 8 is a cross-sectional view schematically illustrating a display device according to an embodiment.

FIG. 9 is a cross-sectional view schematically illustrating sub-pixels adjacent to each other.

FIGS. 10 and 11 are cross-sectional views schematically illustrating a light emitting element according to an embodiment.

FIG. 12 is a flowchart schematically illustrating a method of manufacturing a display device according to an embodiment.

FIG. 13 is a flowchart schematically illustrating a step of forming a light emitting element layer on a pixel circuit layer according to an embodiment.

FIGS. 14 to 20 are diagrams schematically illustrating, by process steps, a method of manufacturing a display device according to an embodiment.

FIG. 21 is a block diagram illustrating an embodiment of a display system.

FIG. 22 is a perspective view illustrating an application example of the display system of FIG. 21.

FIG. 23 is a diagram illustrating a head-mounted display device worn by a user of FIG. 22.

### DETAILED DESCRIPTION

As the present disclosure allows for various changes and numerous embodiments, particular embodiments will be illustrated in the drawings and described in detail in the written description. However, this is not intended to limit the present disclosure to particular modes of practice, and it is to be appreciated that all changes, equivalents, and substitutes that do not depart from the spirit and technical scope of the present disclosure are encompassed in the present disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the present disclosure. Similarly, the second element could also be termed the first element. In the disclosure, the singular expressions are intended to include the plural expressions as well, unless the context clearly indicates otherwise.

It will be further understood that the terms “comprise”, “include”, “have”, etc. used in the disclosure, specify the presence of stated features, integers, steps, operations, elements, components, and/or combinations of them but do not preclude the presence or addition of one or more other features, integers, steps, operations, elements, components, and/or combinations thereof. In addition, when a first part such as a layer, film, region, plat, etc. is on a second part, the first part may be not only “directly on” the second part but a third part may intervene between them. Furthermore, in the disclosure, when a first part such as a layer, film, region, plat, etc. is formed on a second part, a direction in which the first part is formed is not limited to an upper direction of the second part but may include a side or a lower direction of the second part. To the contrary, when a first part such as a layer, film, region, plat, etc. is “under” a second part, the first part may be not only “directly under” the second part but a third part may intervene between them.

The present disclosure relates to a display device and a method of manufacturing the same. Hereinafter, a display device according to embodiments will be described with reference to the attached drawings.

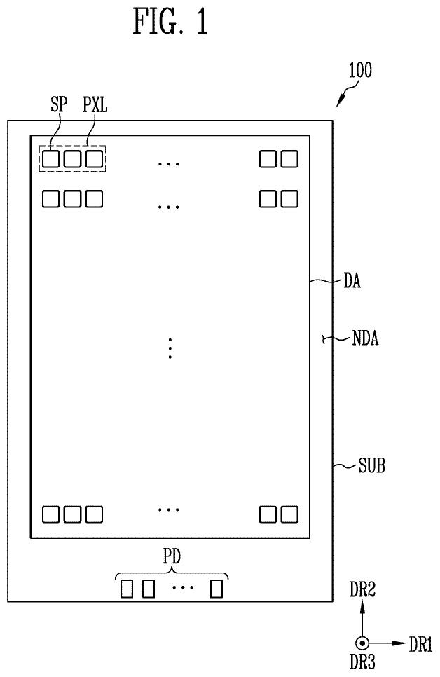

FIG. 1 is a plan view schematically illustrating a display device according to an embodiment.

Referring to FIG. 1, a display device 100 according to an embodiment may be configured to emit light.

The display device 100 may include a display area DA and a non-display area NDA. The display device 100 may display an image through the display area DA. The non-display area NDA may be disposed around the display area DA.

The display device 100 may include a substrate SUB, sub-pixels SP, and pads PD.

The display device 100 may be applied to various fields. For example, the display device 100 may be used as a display screen for a head-mounted display (“HMD”) device, a virtual reality (“VR”) device, a mixed reality (“MR”) device, an augmented reality (“AR”) device, or the like. In this case, the display device 100 may be positioned very close to the user's eyes. Accordingly, the sub-pixels SP with relatively high integration may be desirable. In order to increase the integration of the sub-pixels SP, the substrate SUB may be provided as a silicon substrate. The sub-pixels SP and/or the display device 100 may be disposed on the substrate SUB, which is a silicon substrate. The display device 100 including the display device 100 disposed on the substrate SUB that is a silicon substrate may be referred to as an OLED on Silicon (“OLEDoS”) display device.

The sub-pixels SP may be disposed (or formed) in the display area DA on the substrate SUB. The sub-pixels SP may be arranged in a matrix form along a first direction DR1 and a second direction DR2 different from (for example, intersecting) the first direction DR1. However, embodiments of the present disclosure are not limited thereto. For another example, the sub-pixels SP may be arranged in a zigzag shape along the first direction DR1 and the second direction DR2. For example, the sub-pixels SP may be arranged in a PENTILE™ shape. The first direction DR1 may be a row direction, and the second direction DR2 may be a column direction.

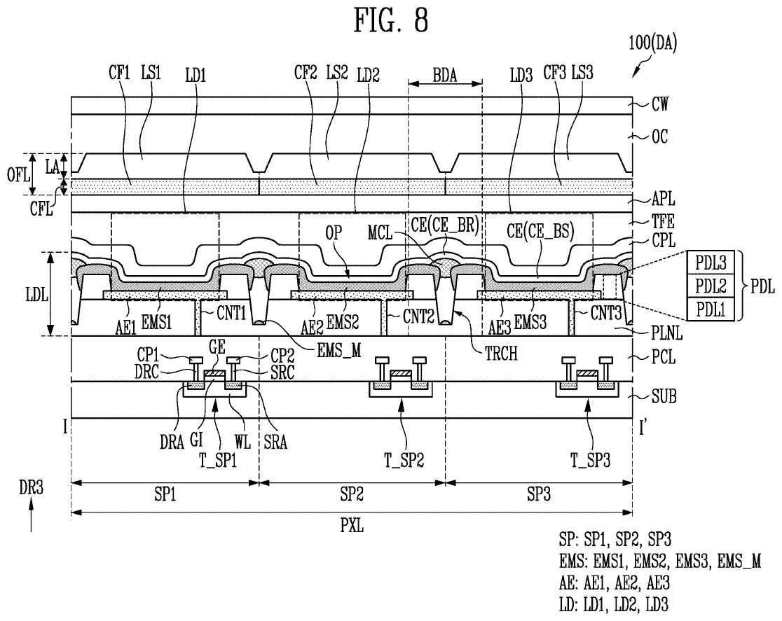

Each of the sub-pixels SP may include at least one light emitting element LD (see FIG. 8) configured to generate light. Accordingly, each of the sub-pixels SP may generate light of a specific color, such as red, green, blue, cyan, magenta, or yellow. Two or more sub-pixels SP among the sub-pixels SP may constitute a pixel PXL. For example, as shown in FIG. 1, three sub-pixels SP may form a pixel PXL.

Hereinafter, the description will be based on an embodiment in which the sub-pixels SP include a first sub-pixel SP1 providing light of a first color (for example, red), a second sub-pixel SP2 providing light of a second color (for example, green), and a third sub-pixel SP3 providing light of a third color (for example, blue).

According to an embodiment, the first sub-pixel SP1 may be a red pixel and may provide light in a wavelength band of 600 nm to 750 nm. The second sub-pixel SP2 may be a green pixel and may provide light in a wavelength band of 480 nm to 560 nm. The third sub-pixel SP3 may be a blue pixel and may provide light in a wavelength band of 370 nm to 460 nm.

Components for controlling the sub-pixels SP may be disposed in the non-display area NDA on the substrate SUB. For example, wirings (for example, gate lines, data lines, and the like for driving the sub-pixels SP) connected to the sub-pixels SP may be disposed in the non-display area NDA. In addition, a gate driver, a data driver, a voltage generator, a controller, a temperature sensor, and/or the like for acquiring driving signals to be supplied to the sub-pixels SP may be integrated in the non-display area NDA of the display device 100. However, the present disclosure is not limited thereto.

The pads PD may be disposed in the non-display area NDA on the substrate SUB. The pads PD may be electrically connected to the sub-pixels SP through wirings. For example, the pads PD may be connected to the sub-pixels SP through data lines.

The pads PD may interface components within the display area DA and the non-display area NDA with other components of the display device 100. In some embodiments, voltages and signals for the operation of components included in the display device 100 may be provided from a driver integrated circuit through the pads PD. For example, the data lines may be electrically connected to the driver integrated circuit through the pads PD. For example, power source voltages for driving the sub-pixels SP may be received from the driver integrated circuit through the pads PD. For example, a gate control signal for controlling the gate driver may be transmitted from the driver integrated circuit to the gate driver through the pads PD.

In some embodiments, a circuit board may be electrically connected to the pads PD using a conductive adhesive member such as an anisotropic conductive film. In this case, the circuit board may be a flexible circuit board (“FPCB”) or a flexible film made of a flexible material. The driver integrated circuit may be mounted on the circuit board and electrically connected to the pads PD.

In some embodiments, the display area DA may have various shapes. The display area DA may have a closed loop shape including straight and/or curved sides. For example, the display area DA may have a shape such as a polygon, circle, semicircle, or ellipse.

In some embodiments, the display device 100 may have a flat display surface. In other embodiments, the display device 100 may have a display surface that is at least partially round. In some embodiments, the display device 100 may be bent, folded, or rolled. In these cases, the display device 100 and/or the substrate SUB may include materials having flexible properties.

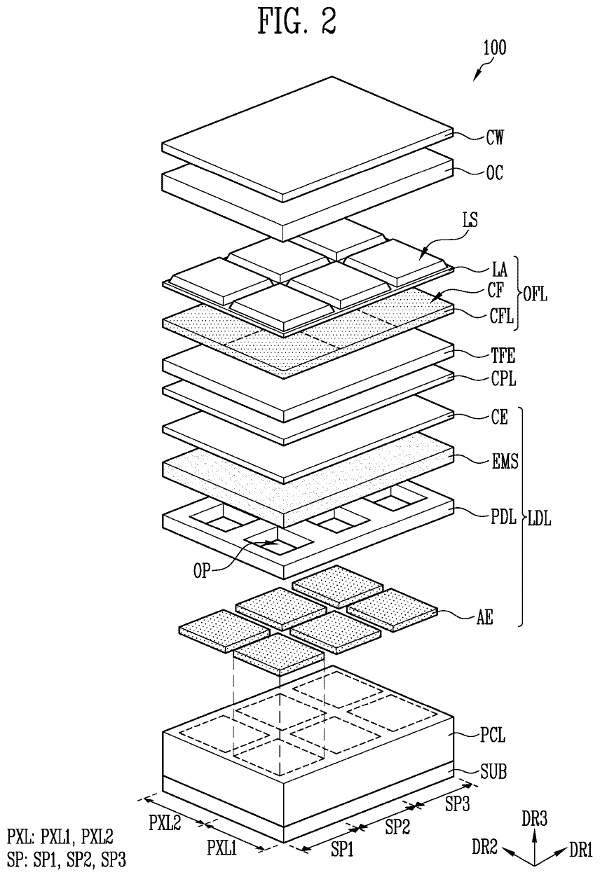

FIG. 2 is an exploded perspective view schematically illustrating a portion of a display panel of FIG. 1. In FIG. 2, for clear and concise description, a portion of the display panel DP corresponding to two pixels PXL1 and PXL2 among pixels PXL of FIG. 1 is schematically shown. Other portions of the display panel DP corresponding to the remaining pixels may be configured similarly.

Referring to FIGS. 1 and 2, each of first and second pixels PXL1 and PXL2 may include first to third sub-pixels SP1 to SP3. However, embodiments of the present disclosure are not limited thereto. For another example, each of the first and second pixels PXL1 and PXL2 may include four sub-pixels or two sub-pixels.

In FIG. 2, the first to third sub-pixels SP1 to SP3 are shown as having a rectangular shape when viewed from a third direction DR3 intersecting the first and second directions DR1 and DR2 and having the same sizes. However, embodiments of the present disclosure are not limited thereto. The first to third sub-pixels SP1 to SP3 may be modified to have various shapes.

The display panel DP may include a substrate SUB, a pixel circuit layer PCL, a light emitting element layer LDL, a capping layer CPL, an encapsulation layer TFE, an optical functional layer OFL, an overcoat layer OC, and a cover window CW.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (“SOI”) layer, or a semiconductor on insulator (“SeOI”) layer. In other embodiments, the substrate SUB may include a glass substrate. In still other embodiments, the substrate SUB may include a polyimide (“PI”) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may function as at least portions of circuit elements, wirings, and/or the like. The conductive patterns may include copper, but embodiments of the present disclosure are not limited thereto.

The circuit elements may include a sub-pixel circuit for each of the first to third sub-pixels SP1 to SP3. The sub-pixel circuit may include transistors and one or more capacitors. Each transistor may include a semiconductor portion including a source region, a drain region, and a channel region, and a gate electrode overlapping the semiconductor portion in a plan view. In some embodiments, when the substrate SUB is provided as a silicon substrate, the semiconductor portion may be included within the substrate SUB, and the gate electrode may be included within the pixel circuit layer PCL as a conductive pattern of the pixel circuit layer PCL. In some embodiments, when the substrate SUB is provided as a glass substrate or a PI substrate, the semiconductor portion and the gate electrode may be included within the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The plane defined in this specification is a direction extending in the first direction DR1 and the second direction DR2 and may be defined based on the plane on which the substrate SUB is disposed. According to an embodiment, the third direction DR3 may be a thickness direction of the substrate SUB, and the third direction DR3 may be a direction in which light is output from the display device 100.

Wirings of the pixel circuit layer PCL may include signal lines connected to each of the first to third sub-pixels SP1 to SP3, for example, a gate line, an emission control line, a data line, and the like.

The light emitting element layer LDL may include anode electrodes AE, a pixel defining layer PDL, a light emitting structure EMS, and a cathode electrode CE.

The anode electrodes AE may be disposed on the pixel circuit layer PCL. The anode electrodes AE may be electrically connected to the circuit elements of the pixel circuit layer PCL.

The pixel defining layer PDL may be disposed on the anode electrodes AE. The pixel defining layer PDL may define an opening OP therein exposing a portion of each of the anode electrodes AE. The opening OP of the pixel defining layer PDL may be understood as an emission area corresponding to each of the first to third sub-pixels SP1 to SP3.

At least a portion of the light emitting structure EMS may be disposed on the anode electrodes AE exposed by the opening OP of the pixel defining layer PDL. The light emitting structure EMS may include a light emitting layer EML configured to generate light, an electron transport unit ETU configured to transport electrons, a hole transport unit HTU configured to transport holes, and/or the like.

In some embodiments, the light emitting structure EMS may fill the opening OP of the pixel defining layer PDL but may be disposed on an entirety of an upper surface of the pixel defining layer PDL. In other words, the light emitting structure EMS may be disposed over the first to third sub-pixels SP1 to SP3. In this case, at least some of layers in the light emitting structure EMS may be discontinued or bent at boundaries between the first to third sub-pixels SP1 to SP3. However, embodiments of the present disclosure are not limited thereto. For another example, portions of the light emitting structure EMS corresponding to the first to third sub-pixels SP1 to SP3 may be separated from each other, and each of them may be disposed within the opening OP of the pixel defining layer PDL.

The cathode electrode CE may be disposed on the light emitting structure EMS. The cathode electrode CE may extend across the first to third sub-pixels SP1 to SP3. In this way, the cathode electrode CE may serve as a common electrode for the first to third sub-pixels SP1 to SP3.

The cathode electrode CE may be a thin metal layer having a thickness sufficient to transmit light emitted from the light emitting structure EMS. The cathode electrode CE may be formed of or include a metal material or a transparent conductive material to have a relatively thin thickness. In some embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), and mixtures thereof. However, the material of the cathode electrode CE is not limited thereto.

It may be understood that one of the anode electrodes AE, a portion of the light emitting structure EMS overlapping the anode electrode in a plan view, and a portion of the cathode electrode CE overlapping the anode electrode in a plan view constitute a light emitting element LD (see FIG. 8). In other words, each of light emitting elements of the first to third sub-pixels SP1 to SP3 may include an anode electrode, a portion of the light emitting structure EMS overlapping the anode electrode, and a portion of the cathode electrode CE overlapping the anode electrode in a plan view. In each of the first to third sub-pixels SP1 to SP3, holes injected from the anode electrode AE and electrons injected from the cathode electrode CE may be transported into the light emitting layer of the light emitting structure EMS to generate excitons, and light can be generated as the excitons transition from an excited state to a ground state. Luminance of the light may be determined depending on the amount of current flowing through the light emitting layer. Depending on the configuration of the light emitting layer, a wavelength range of the generated light may be determined.

The capping layer CAP may be disposed on the cathode electrode CE. The capping layer CPL may protect the light emitting element layer LDL and/or the pixel circuit layer PCL.

The encapsulation layer TFE may be disposed on the capping layer CPL. The encapsulation layer TFE may cover the light emitting element layer LDL and/or the pixel circuit layer PCL. In some embodiments, the encapsulation layer TFE may include a structure in which one or more inorganic layers and one or more organic layers are alternately stacked. For example, the inorganic layer may include silicon nitride, silicon oxide, or silicon oxynitride (SiOxNy). For example, the organic layer may include an organic insulating material such as an acrylic resin, an epoxy resin, a phenol resin, a polyamide resin, a polyimide resin, an unsaturated polyester resin, a polyphenylene resin, a polyphenylene sulfide resin, or benzocyclobutene (“BCB”). However, the materials of the organic and inorganic layers constituting the encapsulation layer TFE are not limited thereto.

To improve the encapsulation effect of the encapsulation layer TFE, the encapsulation layer TFE may further include a thin film including aluminum oxide (AlOx). The thin film including aluminum oxide may be positioned on an upper surface of the encapsulation layer TFE facing the optical function layer OFL and/or on a lower surface of the encapsulation layer TFE facing the light emitting element layer LDL.

The thin film including aluminum oxide may be formed through an atomic layer deposition (“ALD”) method. However, embodiments of the present disclosure are not limited thereto. The encapsulation layer TFE may further include a thin film formed of or include at least one of various materials suitable for improving the encapsulation effect.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may be configured to filter the light emitted from the light emitting structure EMS and selectively output light in a wavelength range or color corresponding to each sub-pixel. The color filter layer CFL may include color filters CF corresponding to the first to third sub-pixels SP1 to SP3. Each of the color filters CF may pass through light in a wavelength range corresponding to the corresponding sub-pixel. For example, a color filter corresponding to the first sub-pixel SP1 may passe red light, a color filter corresponding to the second sub-pixel SP2 may passe green light, and a color filter corresponding to the third sub-pixel SP3 may pass blue light. Depending on the light emitted from the light emitting structure EMS of each sub-pixel, at least some of the color filters CF may be omitted.

The lens array LA may be disposed on the color filter layer CFL. The lens array LA may include lenses LS corresponding to the first to third sub-pixels SP1 to SP3. Each of the lenses LS may improve light output efficiency by outputting the light emitted from the light emitting structure EMS through an intended path. The lens array LA may have a relatively high refractive index. For example, the lens array LA may have a higher refractive index than the overcoat layer OC. In some embodiments, the lenses LS may include an organic material. In some embodiments, the lenses LS may include an acrylic material. However, the material of the lenses LS is not limited thereto.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting its underlying layers from foreign substances such as dust, moisture, or the like. For example, the overcoat layer OC may include at least one of an inorganic insulating layer and an organic insulating layer. For example, the overcoat layer OC may include epoxy, but embodiments of the present disclosure are not limited thereto. The overcoat layer OC may have a lower refractive index than the lens array LA in another embodiment.

The cover window CW may be disposed on the overcoat layer OC. The cover window CW may be configured to protect its underlying layers. The cover window CW may have a higher refractive index than the overcoat layer OC. The cover window CW may include glass, but embodiments of the present disclosure are not limited thereto. For another example, the cover window CW may be an encapsulation glass configured to protect components disposed thereunder. In other embodiments, the cover window CW may be omitted.

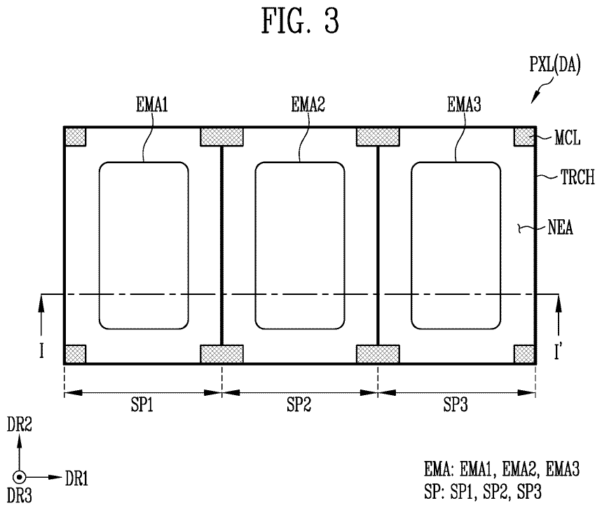

According to an embodiment, the display device 100 may further include an intermediate connection layer MCL (see FIG. 3) between the light emitting structure EMS and the cathode electrode CE.

Hereinafter, the display device 100 including the intermediate connection layer MCL according to embodiments will be described with reference to FIGS. 3 to 11.

First, a planar structure of the display device 100 according to embodiments will be described with reference to FIGS. 3 to 7.

FIG. 3 is a plan view schematically illustrating a pixel according to an embodiment. As used herein, the “plan view” is a view in thickness direction DR3 of the substrate SUB (See FIG. 8).

Referring to FIG. 3, a pixel PXL may include sub-pixels SP arranged in the first direction DR1. The sub-pixels SP may include a first sub-pixel SP1, a second sub-pixel SP2, and a third sub-pixel SP3 arranged in the first direction DR1.

The sub-pixels SP may include emission areas EMA. For example, the emission areas EMA may include a first emission area EMA1, a second emission area EMA2, and a third emission area EMA3. The first sub-pixel SP1 may include the first emission area EMA1 and a non-emission area NEA around the first emission area EMA1. The second sub-pixel SP2 may include the second emission area EMA2 and a non-emission area NEA around the second emission area EMA2. The third sub-pixel SP3 may include the third emission area EMA3 and a non-emission area NEA around the third emission area EMA3.

The first emission area EMA1 may be an area where light is emitted from a portion of the light emitting structure EMS corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3. As described above, each emission area EMA may be understood as an opening OP in a pixel defining layer PDL corresponding to each of the first sub-pixel SP1, the second sub-pixel SP2, and the third sub-pixel SP3.

According to an embodiment, the pixel PXL (or the display device 100) may further include a trench TRCH and the intermediate connection layer MCL.

The trench TRCH may form a separating structure between adjacent sub-pixels SP. For example, the trench TRCH may cause at least a portion of the light emitting structure EMS to break. The trench TRCH may allow at least a portion of the light emitting structure EMS to be formed discontinuously.

The trench TRCH may cut at least a portion of the light emitting structure EMS continuously disposed between adjacent sub-pixels SP. Accordingly, the risk of leakage current occurring between adjacent sub-pixels SP can be effectively reduced.

The trench TRCH may be formed around the emission area EMA of each of the sub-pixels SP. The trench TRCH may overlap the non-emission area EMA.

In an embodiment, only one trench TRCH may be defined, but according to some embodiments, a plurality of trenches TRCH may be defined between adjacent sub-pixels SP. However, the present disclosure is not limited thereto. Hereinafter, for convenience of description, the description will be based on an embodiment in which only one trench TRCH is formed between adjacent sub-pixels SP.

The intermediate connection layer MCL may overlap the trench TRCH in a plan view. The intermediate connection layer MCL may be disposed in the non-emission area NEA. The intermediate connection layer MCL may be disposed around the emission area EMA.

According to an embodiment, the intermediate connection layer MCL may be provided in plurality. The plurality of intermediate connection layers MCL may be spaced apart from each other. The plurality of intermediate connection layers MCL may be formed at edges of the sub-pixels SP.

According to an embodiment, when the sub-pixels SP have a polygonal shape, each of the plurality of intermediate connection layers MCL may be disposed at each of the vertices of the polygonal shape defined by the sub-pixels SP. For example, as shown in FIG. 3, when the sub-pixels SP have an approximately square shape, the plurality of intermediate connection layers MCL may be disposed at four vertices of each of the sub-pixels SP.

According to an embodiment, as the display device 100 includes the trench TRCH, the risk of leakage current and the like can be effectively reduced. In addition, as the display device 100 includes the intermediate connection layers MCL, a detailed cathode connection structure can be formed. Further details in this regard will be described later with reference to the drawings after FIG. 8.

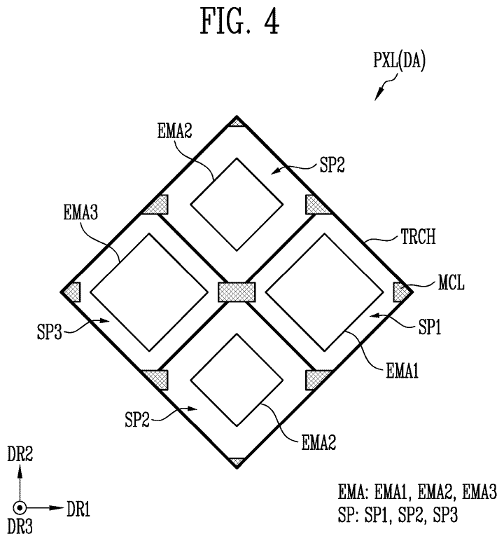

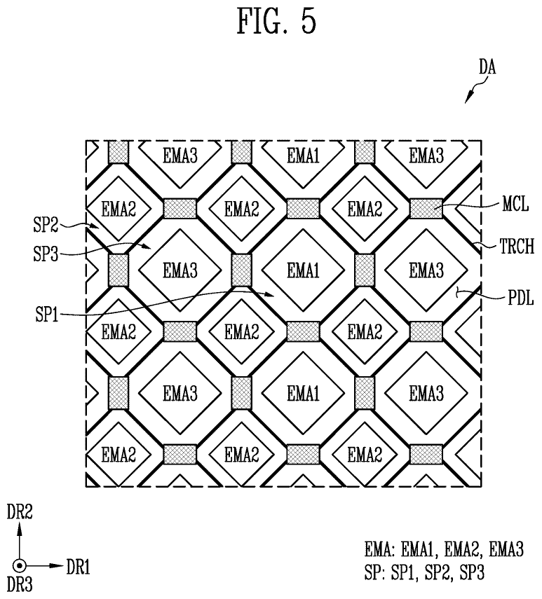

FIGS. 4 and 5 are plan views schematically illustrating the pixel according to an embodiment.

Referring to FIGS. 4 and 5, a pixel PXL according to an embodiment may be different from the pixel PXL described with reference to FIG. 3 in that first to third sub-pixels SP1 to SP3 are arranged in a diamond shape.

According to an embodiment, the pixel PXL may include one first sub-pixel SP1, two second sub-pixels SP2, and one third sub-pixel SP3. The first sub-pixel SP1 and the third sub-pixel SP3 may be adjacent to each other in the first direction DR1, and the second sub-pixels SP2 may be adjacent to each other in the second direction DR2. According to an embodiment, the first and third sub-pixels SP1 and SP3 may have a larger area than the second sub-pixel SP2.

According to an embodiment, a trench TRCH may be disposed around each of emission areas EMA. An intermediate connection layer MCL may be disposed at each of the vertices of each of the sub-pixels SP.

Meanwhile, referring to FIG. 5, a pixel defining layer PDL according to an embodiment may be disposed at the periphery of the emission area EMA. At least a portion of the pixel defining layer PDL may be removed to form the trench TRCH.

Intermediate connection layers MCL may not be formed an entire area between adjacent sub-pixels SP, but may be selectively disposed in a portion of an area between adjacent sub-pixels SP.

As the intermediate connection layers MCL are formed at the vertices of each of the sub-pixels SP, a cathode electrode CE can be formed in detail in the sub-pixels SP within the display area DA, and the risk of voltage drop or the like can be effectively reduced.

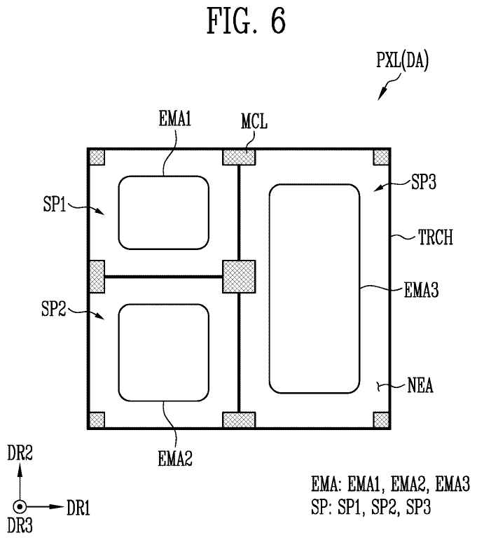

FIG. 6 is a plan view schematically illustrating a pixel according to an embodiment.

Referring to FIG. 6, a pixel PXL may include first to third sub-pixels SP1 to SP3, at least some of which have different areas. According to an embodiment, the third sub-pixel SP3 may have a larger area than the first sub-pixel SP1. The third sub-pixel SP3 may have a larger area than the second sub-pixel SP2. According to an embodiment, the second sub-pixel SP2 may have a larger area than the first sub-pixel SP1 or may have the same area as the first sub-pixel SP1. According to an embodiment, the first and second sub-pixels SP1 and SP2 may be adjacent to each other in the second direction DR2. The third sub-pixel SP3 may be adjacent to the first sub-pixel SP1 along the first direction DR1 and may be adjacent to the second sub-pixel SP2 along the first direction DR1.

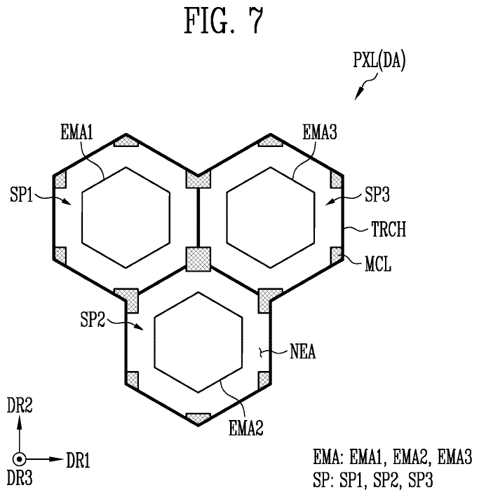

FIG. 7 is a plan view schematically illustrating a pixel according to an embodiment.

Referring to FIG. 7, first to third sub-pixels SP1 to SP3 may have a polygonal shape. For example, the first to third sub-pixels SP1 to SP3 may have a hexagonal shape. The first and third sub-pixels SP1 and SP3 may be arranged in the first direction DR1. The second sub-pixel SP2 may be disposed in a direction inclined at an acute angle (or diagonally) with respect to the second direction DR2 with respect to the first sub-pixel SP1.

However, the structure in which sub-pixels SP, emission areas EMA, and intermediate connection layers MCL are arranged is not necessarily limited to the examples described above.

Next, a cross-sectional structure of the display device 100 according to embodiments will be described with reference to FIGS. 8 to 11.

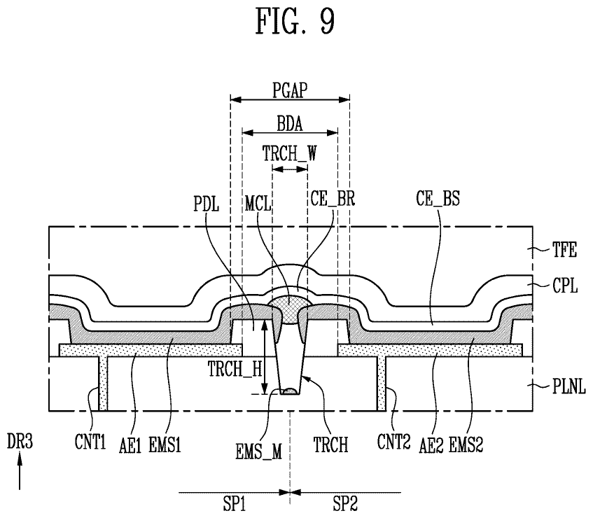

FIG. 8 is a cross-sectional view schematically illustrating a display device according to an embodiment. FIG. 9 is a cross-sectional view schematically illustrating sub-pixels adjacent to each other.

FIGS. 8 and 9 schematically show the cross-sectional structure of the display device 100 within the display area DA. For convenience of description, FIG. 8 schematically shows the first to third sub-pixels SP to SP3, and FIG. 9 schematically shows the light emitting element LD and structures adjacent thereto.

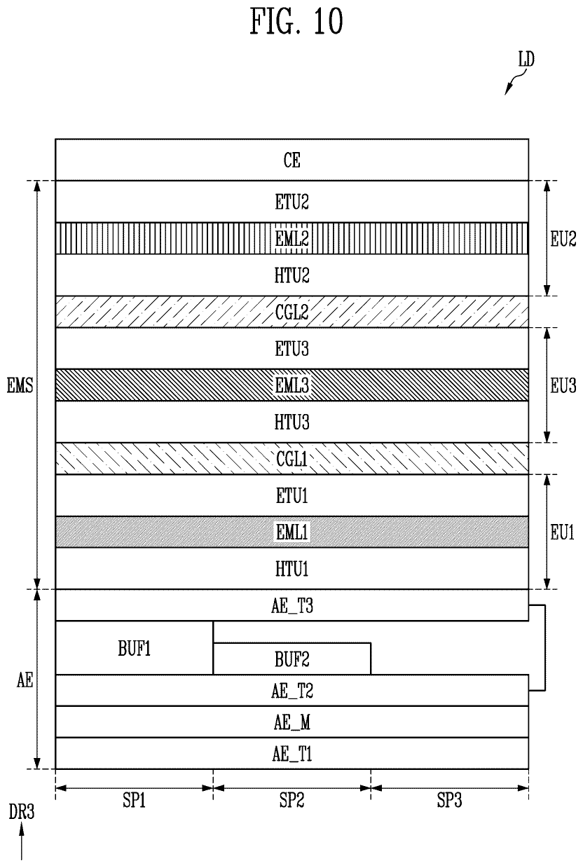

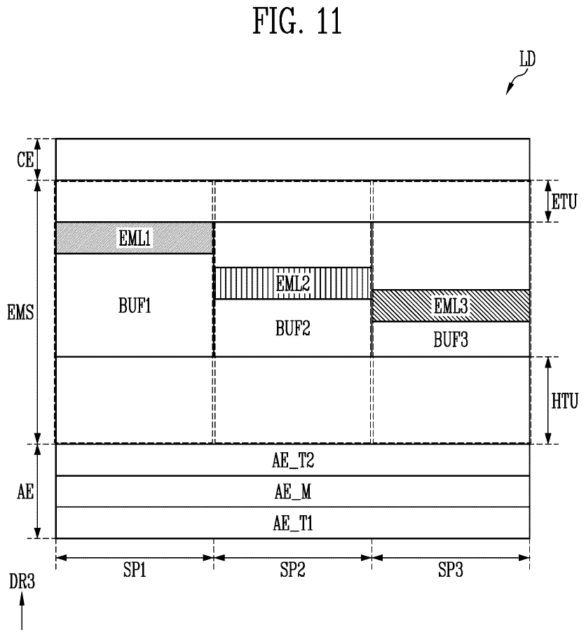

FIGS. 10 and 11 are cross-sectional views schematically illustrating a light emitting element according to an embodiment. FIG. 10 schematically shows the light emitting element LD including a tandem structure. FIG. 11 schematically shows light emitting elements LD that can emit light of a color from the sub-pixels SP.

According to an embodiment, the substrate SUB and the pixel circuit layer PCL disposed on the substrate SUB may be provided.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of transistors included in a sub-pixel circuit of the first sub-pixel SP1. The transistor T_SP2 of the second sub-pixel SP2 may be any one of transistors included in a sub-pixel circuit of the second sub-pixel SP2. The transistor T_SP3 of the third sub-pixel SP3 may be any one of transistors included in a sub-pixel circuit of the third sub-pixel SP3. In FIG. 8, for clear and concise description, one of transistors of each sub-pixel is shown, and the remaining circuit elements are omitted.

The transistor T_SP1 of the first sub-pixel SP1 may include a source region SRA, a drain region DRA, and a gate electrode GE.

The source region SRA and the drain region DRA may be disposed within the substrate SUB. A well WL formed through an ion implantation process may be disposed within the substrate SUB, and the source region SRA and the drain region DRA may be disposed to be spaced apart from each other within the well WL. A region between the source region SRA and the drain region DRA within the well WL may be defined as a channel region.

The gate electrode GE may overlap the channel region between the source region SRA and the drain region DRA in a plan view and may be disposed in the pixel circuit layer PCL. The gate electrode GE may be spaced apart from the well WL or the channel region by an insulating material such as a gate insulating layer GI. The gate electrode GE may include a conductive material.

A plurality of layers included in the pixel circuit layer PCL may include insulating layers and conductive patterns disposed between the insulating layers. Such conductive patterns may include first and second conductive patterns CP1 and CP2. The first conductive pattern CP1 may be electrically connected to the drain region DRA through a drain connection portion DRC penetrating one or more insulating layers. The second conductive pattern CP2 may be electrically connected to the source region SRA through a source connection portion SRC penetrating one or more insulating layers.

As the gate electrode GE and the first and second conductive patterns CP1 and CP2 are connected to other circuit elements and/or wirings, the transistor T_SP1 of the first sub-pixel SP1 may be provided as any one of transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As such, the substrate SUB and the pixel circuit layer PCL may include circuit elements of each of the first to third sub-pixels SP1 to SP3.

The light emitting element layer LDL may be disposed on the pixel circuit layer PCL. The light emitting element layer LDL may include a planarization layer PLNL, an anode electrode AE, a pixel defining layer PDL, a light emitting structure EMS, a cathode electrode CE, a capping layer CPL, and an encapsulation layer TFE.

The planarization layer PLNL may cover the pixel circuit layer PCL, but may have an overall flat surface. The planarization layer PLNL may include an organic material. According to an embodiment, the planarization layer PLNL may be a via-layer.

The anode electrode AE may be disposed on the planarization layer PLNL. The anode electrode AE may include a first anode electrode AE1 forming a first light emitting element LD1 in the first sub-pixel SP1, a second anode electrode AE2 forming a second light emitting element LD2 in the second sub-pixel SP2, and a third anode electrode AE3 forming a third light emitting element LD3 in the third sub-pixel SP3.

The first anode electrode AE1 may be electrically connected to a first transistor T_SP1 through a first contact portion CNT1 penetrating the planarization layer PLNL. The first contact portion CNT1 may further be defined in at least a portion of the pixel circuit layer PCL. The second anode electrode AE2 may be electrically connected to a second transistor T_SP2 through a second contact portion CNT2 penetrating the planarization layer PLNL. The second contact portion CNT2 may further be defined in at least a portion of the pixel circuit layer PCL. The third anode electrode AE3 may be electrically connected to a third transistor T_SP3 through a third contact portion CNT3 penetrating the planarization layer PLNL. The third contact portion CNT3 may further be defined in at least a portion of the pixel circuit layer PCL.

The anode electrode AE may include various conductive materials. The anode electrode AE may supply an anode signal (for example, a voltage) so that the light emitting element LD emits light, and may form a light recycling structure (for example, a resonance structure) to improve the light output efficiency of the light emitting element LD.

For example (see FIGS. 10 and 11), the anode electrode AE may include a first anode transparent portion AE_T1, an anode reflective portion AE_M, a second anode transparent portion AE_T2, and a third anode transparent portion AE_T3. According to an embodiment, in the first to third sub-pixels SP1 to SP3, the second anode transparent portion AE_T2 and the third anode transparent portion AE_T3 may be electrically connected to each other.

The first to third anode transparent portions AE_T1 to AE_T3 may include at least one of transparent conductive materials such as indium tin oxide (“ITO”), indium zinc oxide (“IZO”), zinc oxide (ZnOx), indium gallium zinc oxide (“IGZO”), and indium tin zinc oxide (“ITZO”). The anode reflective portion AE_M may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, the present disclosure is not limited thereto.

According to an embodiment (see FIG. 10), the first anode electrode AE1 may further include a first anode buffer portion BUF1. The second anode electrode AE2 may further include a second anode buffer portion BUF2. The first and second anode buffer portions BUF1 and BUF2 may adjust the heights of upper surfaces of the first and second anode electrodes AE1 and AE2 in the first and second sub-pixels SP1 and SP2. Accordingly, the distance between the anode electrodes AE and the cathode electrode CE can be adjusted for each sub-pixel SP.

The pixel defining layer PDL may be disposed on the anode electrode AE and the planarization layer PLNL. The pixel defining layer PDL may include the opening OP exposing a portion of each of the first to third anode electrodes AE1 to AE3. The opening OP of the pixel defining layer PDL may define the emission areas EMA1 to EMA3 of the first to third sub-pixels SP1 to SP3.

In some embodiments, the pixel defining layer PDL may include a plurality of inorganic insulating layers. For example, the pixel defining layer PDL may include a first pixel defining layer PDL1, a second pixel defining layer PDL2, and a third pixel defining layer PDL3. Each of the first to third pixel defining layers PDL1 to PDL3 may include at least one of silicon oxide (SiOx) and silicon nitride (SiNx). For example, the first pixel defining layer PDL1 may include silicon nitride, the second pixel defining layer PDL2 may include silicon oxide, and the third pixel defining layer PDL3 may include silicon nitride. However, embodiments of the present disclosure are not limited thereto. The first to third pixel defining layers PDL1 to PDL3 may have a step-shaped cross section in an area adjacent to the opening OP in another embodiment.

According to an embodiment, the width PGAP of the pixel defining layer PDL may be 9 micrometers (μm) or less. For example, the width PGAP of the pixel defining layer PDL may be 0.5 μm to 3.5 μm. For example, the width PGAP of the pixel defining layer PDL defined between adjacent sub-pixels SP may be about 2 μm. Here, the width PGAP may be a width of a portion of the pixel defining layer PDL between adjacent emission areas EMA as shown in FIGS. 3 and 9.

Accordingly, the size of the non-emission area NEA formed by the pixel defining layer PDL can be reduced, and thus the display device 100 having high-resolution characteristics can be provided. According to an embodiment, the width PGAP of the pixel defining layer PDL may be reduced as the intermediate connection layer MCL according to the embodiment is formed. Details regarding this will be described later.

As described above, the trench TRCH may be defined in a boundary area BDA between adjacent sub-pixels SP. In an embodiment, the boundary area BDA may be defined as an area between adjacent anode electrodes AE. The trench TRCH may be defined in the pixel defining layer PDL and the planarization layer PLNL. For example, the trench TRCH may entirely penetrate the pixel defining layer PDL and may be defined in the planarization layer PLNL.

The trench TRCH may have a thickness TRCH_H in the thickness direction DR3 of the substrate SUB and a trench width TRCH_W in a direction in which the sub-pixels SP are spaced apart from each other. According to an embodiment, the thickness TRCH_H may be greater than half the thickness of the light emitting structure EMS in the thickness direction DR3. In addition, the trench width TRCH_W may be greater than ¼ of the thickness of the light emitting structure EMS. In this case, common layers (for example, first and second charge generation layers CGL1 and CGL2) for the light emitting structure EMS may be appropriately discontinued.

According to an embodiment, a side surface of the trench TRCH may form an included angle of 60 to 90 degrees with respect to a plane on which the substrate SUB is disposed. However, the present disclosure is not limited thereto.

The trench TRCH may cause a discontinuity to form within the light emitting structure EMS at the boundary area BDA. For example, the light emitting structure EMS may be discontinued or bent at the boundary area BDA by the trench TRCH. The charge generation layers CGL1 and CGL2 included in the light emitting structure EMS may be discontinued by the trench TRCH. For example, referring to FIG. 10, a first light emitting unit EU1, the first charge generation layer CGL1, a third light emitting unit EU3, and the second charge generation layer CGL2 may be cut by the trench TRCH. Accordingly, portions of the light emitting structure EMS included in the first to third sub-pixels SP1 to SP3 may be at least partially separated.

Accordingly, according to an embodiment, even though the light emitting structure EMS is disposed over the sub-pixels SP, leakage current between adjacent sub-pixels SP (for example, in a horizontal direction) can be effectively reduced as the trench TRCH is formed. In addition, a direction of the current for generating light in each sub-pixel SP can be defined as a general vertical direction (that is, a direction from the anode electrode AE to the cathode electrode CE), and the reliability of the light emitting element LD can be effectively improved.

The light emitting structure EMS may be disposed on the anode electrodes AE exposed by the opening OP of the pixel defining layer PDL. The light emitting structure EMS may fill the opening OP of the pixel defining layer PDL, but may be disposed over the first to third sub-pixels SP1 to SP3.

The light emitting structure EMS may include a first light emitting structure EMS1 forming the first light emitting element LD1 in the first sub pixel SP1, a second light emitting structure EMS2 forming the second light emitting element LD2 in the second sub-pixel SP2, a third light emitting structure EMS3 forming the third light emitting element LD3 in the third sub-pixel SP3, and an intermediate light emitting structure EMS_M provided in the boundary area BDA.

According to an embodiment (see FIG. 10), the light emitting structure EMS (for example, each of the first to third light emitting structures EMS1 to EMS3) may have a tandem structure. For example, the light emitting structure EMS may include a first light emitting unit EU1 emitting light of a first color, a second light emitting unit EU2 emitting light of a second color, a third light emitting unit EU3 emitting light of a third color, and charge generation layers CGL1 and CGL2.

According to an embodiment, in the light emitting structure EMS, the first light emitting unit EU1, the first charge generation layer CGL1, the third light emitting unit EU3, the second charge generation layer CGL2, and the second light emitting unit EU2 may be arranged in sequence. However, the present disclosure is not limited thereto.

Each of the light emitting units EU1 to EU3 may include a hole transport unit HTU1 to HTU3, a light emitting layer EML1 to EML3, and an electron transport unit ETU1 to ETU3.

The hole transport unit HTU1 to HTU3 may include a multi-layer structure having a plurality of layers including different materials. As an example, the hole transport unit HTU1 to HTU3 may include at least one of a hole injection layer and a hole transport layer, and according to an embodiment, may further include a light emitting auxiliary layer and an electron blocking layer. For example, the hole transport unit may have a multi-layer structure such as a hole injection layer/hole transport layer, a hole injection layer/hole transport layer/light emitting auxiliary layer, a hole injection layer/light emitting auxiliary layer, a hole transport layer/light emitting auxiliary layer, an electron blocking layer/hole injection layer/hole transport layer, hole transport layers sequentially arranged and including different materials, or a hole injection layer/hole transport layer/electron blocking layer. However, the present disclosure is not limited to specific examples.

The light emitting layer EML1 to EML3 may include a material configured to emit light of a color. The light emitting layer EML1 to EML3 may include a host and a dopant. The host of the light emitting layer EML1 to EML3 may be a light emitting material that can capture carriers (electrons and holes) generating light, and may induce the efficient generation of excitons. The dopant may include a phosphorescent dopant or a fluorescent dopant. According to an embodiment, examples of the dopant are not particularly limited. According to an embodiment, the dopant may include an organic material, a metal complex, or the like.

The electron transport unit ETU1 to ETU3 may include a multi-layer structure having a plurality of layers including different materials. The electron transport unit ETU1 to ETU3 may include at least one of an electron injection layer and an electron transport layer, and according to an embodiment, may further include an electron buffer layer, a hole blocking layer, and/or the like. For example, the electron transport unit ETU1 to ETU3 may have a multi-layer structure such as an electron transport layer/electron injection layer, a hole blocking layer/electron transport layer/electron injection layer, an electron control layer/electron transport layer/electron injection layer, or a buffer layer/electron transport layer/electron injection layer. However, the present disclosure is not limited to specific examples.

However, the present disclosure is not limited thereto. In another embodiment (see FIG. 11), the light emitting structure EMS may include different light emitting layers EML1 to EML3 for each of the first to third sub-pixels SP1 to SP3. In this case, the first light emitting unit EU1 may be disposed in the first sub-pixel SP1, the second light emitting unit EU2 may be disposed in the second sub-pixel SP2, and the third light emitting unit EU3 may be disposed in the third sub-pixel SP3. In an embodiment, the hole transport unit HTU and the electron transport unit ETU may be a common layer for the first to third sub-pixels SP1 to SP3. In an embodiment, a first buffer layer BUF1 may be disposed between the first light emitting layer EML1 and the hole transport unit HTU within the first sub-pixel SP1 to form a step difference. A second buffer layer BUF2 may be disposed between the second light emitting layer EML2 and the hole transport unit HTU within the second sub-pixel SP2 to form a step difference. A third buffer layer BUF3 may be disposed between the third light emitting layer EML3 and the hole transport unit HTU within the third sub-pixel SP3 to form a step difference. In this case, at least a portion of the light emitting structure EMS cut by the trench TRCH may be the hole transport unit HTU as a common layer for the first to third sub-pixels SP1 to SP3.

The intermediate light emitting structure EMS_M may be formed in the same process as the first to third light emitting structures EMS1 to EMS3 and may include the same materials.

The intermediate light emitting structure EMS_M may be disposed between adjacent sub-pixels SP. The intermediate light emitting structure EMS_M may be disposed within the trench TRCH in the boundary area BDA. The intermediate light emitting structure EMS_M may not overlap the anode electrode AE in a plan view. The intermediate light emitting structure EMS_M may not overlap the pixel defining layer PDL in a plan view.

The intermediate light emitting structure EMS_M may overlap the intermediate connection layer MCL in a plan view. For example, the intermediate light emitting structure EMS_M may be physically spaced apart from the intermediate connection layer MCL, and the intermediate light emitting structure EMS_M may be covered by the intermediate connection layer MCL in a plan view. The intermediate light emitting structure EMS_M may not be in contact with the intermediate connection layer MCL. According to an embodiment, a void may be formed between the intermediate light emitting structure EMS_M and the intermediate connection layer MCL. For example, the pixel defining layer PDL, the planarization layer PLNL, the intermediate light emitting structure EMS_M, and the intermediate connection layer MCL may surround one space, and the void may be defined accordingly. For example, a first portion of the void may be directly adjacent to the pixel defining layer PDL, a second portion of the void may be directly adjacent to the planarization layer PLNL, a third portion of the void may be directly adjacent to the intermediate light emitting structure EMS_M, and a fourth portion of the void may be directly adjacent to the intermediate connection layer MCL. At least a portion of the void may be filled with air. According to an embodiment, the void defined between the intermediate light emitting structure EMS_M and the intermediate connection layer MCL may be referred to as a cavity structure.

The intermediate light emitting structure EMS_M may be formed in a deposition process for forming the light emitting structure EMS and may be manufactured by the trench TRCH. Accordingly, in the display area DA, the intermediate light emitting structure EMS_M may be provided in plurality, and the trench TRCH may be provided in plurality. The number of intermediate light emitting structures EMS_M may be equal to the number of trenches TRCH.

The intermediate connection layer MCL may be disposed between adjacent sub-pixels SP. The intermediate connection layer MCL may overlap the trench TRCH in a plan view. The intermediate connection layer MCL may reduce a step difference formed by the trench TRCH.

The intermediate connection layer MCL may be disposed in the boundary area BDA. The intermediate connection layer MCL may be disposed on the light emitting structure EMS in the boundary area BDA. For example, the intermediate connection layer MCL may connect the first light emitting structure EMS1 and the second light emitting structure EMS2.

The intermediate connection layer MCL may be covered by a portion of the cathode electrode CE (for example, a bridge cathode electrode CE_BR) in the boundary area BDA. The intermediate connection layer MCL may form a bridge in the boundary area BDA to prevent a cathode electrical path formed across the first to third light emitting elements LD1 to LD3 from being discontinued.

For example, the intermediate connection layer MCL may be physically connected to each of adjacent light emitting structures EMS with the trench TRCH therebetween. The intermediate connection layer MCL may be covered by the bridge cathode electrode CE_BR. Accordingly, the risk of the cathode electrode CE being discontinued by the trench TRCH can be effectively reduced, and the common electrode can be formed in detail within the display area DA.

According to an embodiment, the intermediate connection layer MCL may include various materials.

For example, the intermediate connection layer MCL may include an organic material having electron transport properties. For example, the intermediate connection layer MCL may include an organic material forming the electron transport layer.

However, the present disclosure is not limited thereto. For another example, the intermediate connection layer MCL may include a conductive material. Alternatively, according to an embodiment, the intermediate connection layer MCL may include an inorganic material. In other examples, the intermediate connection layer MCL may include other organic materials.

The cathode electrode CE may be disposed on the light emitting structure EMS. The cathode electrode CE may be commonly provided to the first to third sub-pixels SP1 to SP3. The cathode electrode CE may function as a half mirror that partially transmits and partially reflects the light emitted from the light emitting structure EMS.

At least a portion of the cathode electrode CE may be disposed on the intermediate connection layer MCL. The cathode electrode CE may include a base cathode electrode CE_BS and a bridge cathode electrode CE_BR. The base cathode electrode CE_BS may be a part included in the light emitting element LD and may overlap the emission area EMA in a plan view. The bridge cathode electrode CE_BR may be disposed in the boundary area BDA and may overlap the intermediate light emitting structure EMS_M and the intermediate connection layer MCL in a plan view. For example, the bridge cathode electrode CE_BR may contact the intermediate connection layer MCL.

The first anode electrode AE1, a portion of the light emitting structure EMS overlapping the first anode electrode AE1 in a plan view, and a portion of the cathode electrode CE overlapping the first anode electrode AE1 in a plan view may constitute the first light emitting element LD1. The second anode electrode AE2, a portion of the light emitting structure EMS overlapping the second anode electrode AE2 in a plan view, and a portion of the cathode electrode CE overlapping the second anode electrode AE2 in a plan view may constitute the second light emitting element LD2. The third anode electrode AE3, a portion of the light emitting structure EMS overlapping the third anode electrode AE3 in a plan view, and a portion of the cathode electrode CE overlapping the third anode electrode AE3 in a plan view may constitute the third light emitting element LD3.

The capping layer CPL may be disposed on the cathode electrode CE. The capping layer CPL may cap the light emitting elements LD. According to another embodiment, the capping layer CPL may be directly adjacent to the intermediate connection layer MCL in the boundary area BDA (not shown in FIG. 9). According to an embodiment, the capping layer CPL may include an inorganic material or an organic material. The capping layer CPL may have a relatively high refractive index, and accordingly, the light output efficiency of the light emitting element LD can be effectively improved. However, the present disclosure is not limited thereto.

The capping layer CPL may overlap the intermediate light emitting structure EMS_M and the intermediate connection layer MCL in a plan view.

The encapsulation layer TFE may be disposed on the capping layer CPL. The encapsulation layer TFE may prevent oxygen and/or moisture from penetrating into the light emitting element layer LDL.

The optical functional layer OFL may be disposed on the encapsulation layer TFE. In some embodiments, the optical functional layer OFL may be attached to the encapsulation layer TFE through an adhesive layer APL. For example, the optical functional layer OFL may be manufactured separately and attached to the encapsulation layer TFE through the adhesive layer APL. The adhesive layer APL may further perform the function of protecting the layers below, including the encapsulation layer TFE.

The encapsulation layer TFE may overlap the intermediate light emitting structure EMS_M and the intermediate connection layer MCL in a plan view.

The optical functional layer OFL may include a color filter layer CFL and a lens array LA. The color filter layer CFL may include first to third color filters CF1 to CF3 corresponding to the first to third pixels SP1 to SP3. The first to third color filters CF1 to CF3 may pass light of different wavelength ranges. For example, the first to third color filters CF1 to CF3 may pass red, green, and blue light, respectively.

In some embodiments, the first to third color filters CF1 to CF3 may partially overlap each other in a plan view in the boundary area BDA. In other embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 corresponding to the first to third sub-pixels SP1 to SP3. Each of the first to third lenses LS1 to LS3 may improve light output efficiency by outputting the light emitted from the first to third light emitting elements LD1 to LD3 through an intended path.

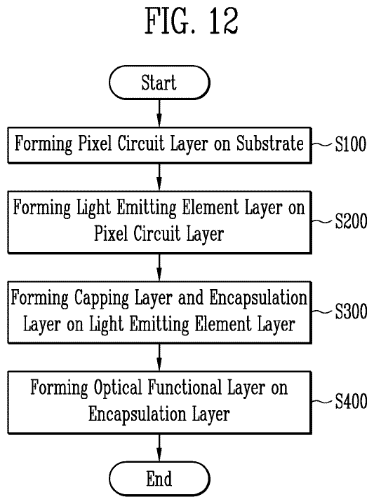

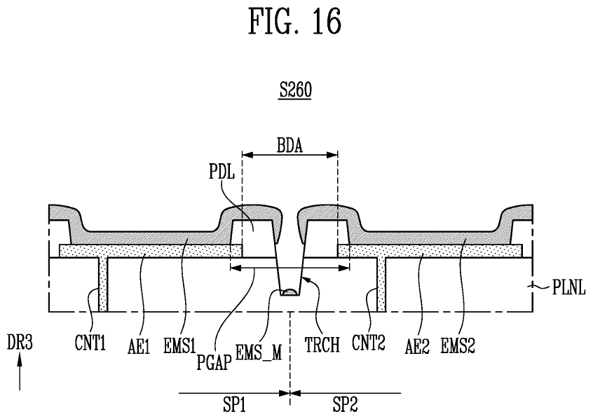

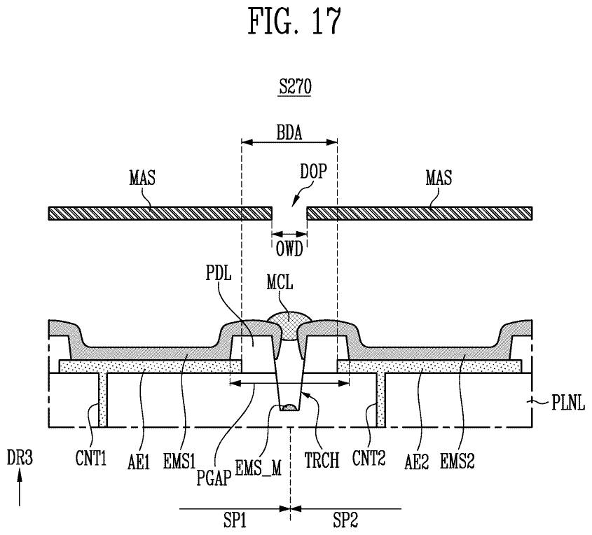

A method of manufacturing the display device 100 according to embodiments will be described with reference to FIGS. 12 to 20. Content that may overlap with the content described above will be briefly described or omitted.

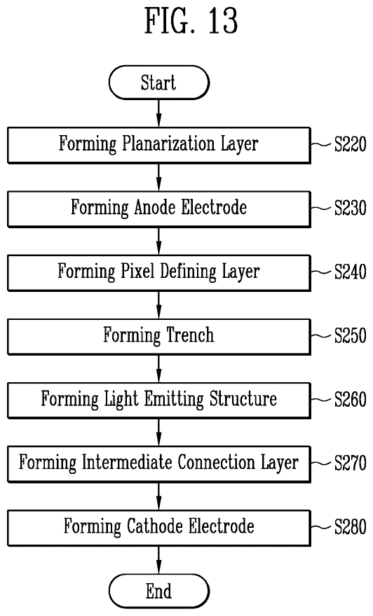

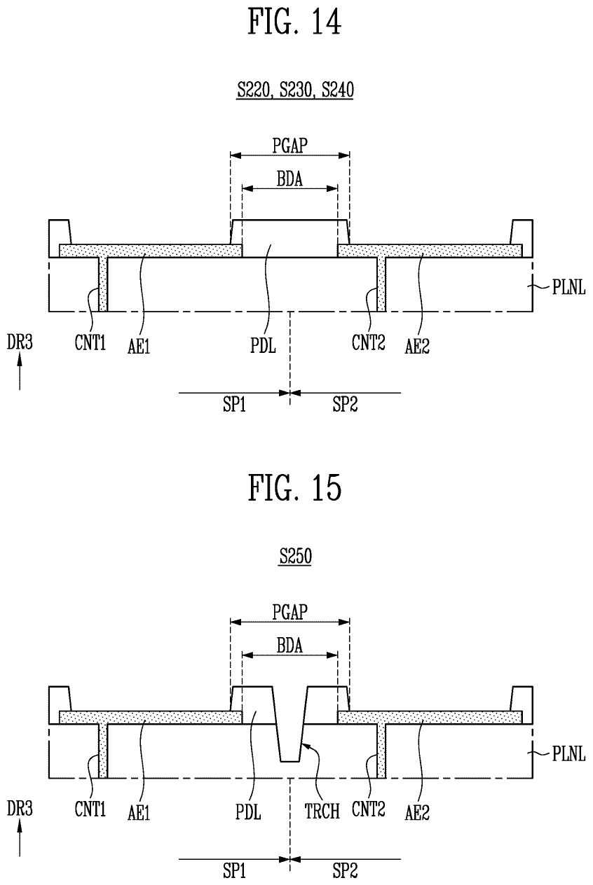

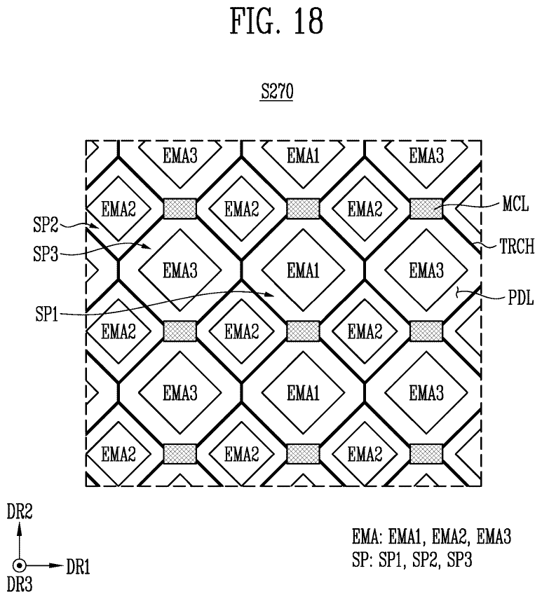

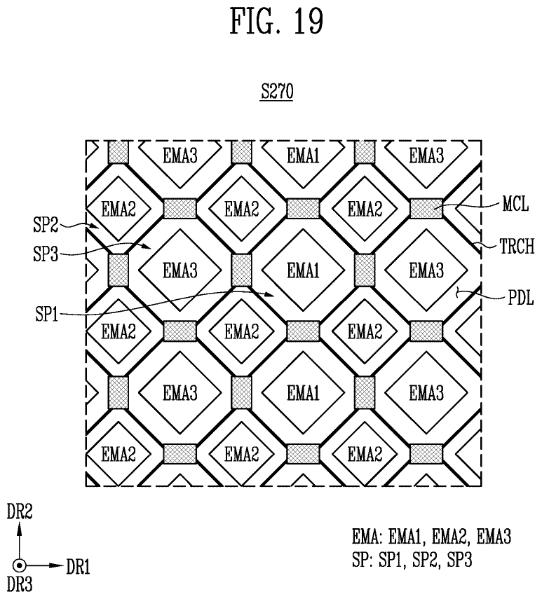

FIG. 12 is a flowchart schematically illustrating a method of manufacturing a display device according to an embodiment. FIG. 13 is a flowchart schematically illustrating a step of forming a light emitting element layer on a pixel circuit layer according to an embodiment. FIGS. 14 to 20 are diagrams schematically illustrating, by process steps, a method of manufacturing a display device according to an embodiment. For convenience of description, FIGS. 14 to 17 and 20 show cross-sections at each process step of the method of manufacturing the display device 100 according to embodiments, based on the cross-sectional structure shown in FIG. 9. FIGS. 18 and 19 show planes at each process step of the method of manufacturing the display device 100 according to embodiments, based on the planar structure shown in FIGS. 4 and 5. Hereinafter, for convenience of description, in order to explain the sub-pixels SP, the method of manufacturing the display device 100 will be described based on the first and second sub-pixels SP1 and SP2 formed adjacent to each other.

Referring to FIG. 12, the method of manufacturing the display device 100 according to embodiments may include forming a pixel circuit layer on a substrate (S100), forming a light emitting element layer on the pixel circuit layer (S200), forming a capping layer and an encapsulation layer on the light emitting element layer LDL (S300), and forming an optical functional layer on the encapsulation layer (S400).

Referring to FIG. 13, the forming of the light emitting element layer on the pixel circuit layer (S200) may include forming a planarization layer (S220), forming an anode electrode (S230), forming a pixel defining layer (S240), forming a trench (S250), forming a light emitting structure (S260), forming an intermediate connection layer (S270), and forming a cathode electrode (S280).

Referring to FIG. 12 in conjunction with FIG. 8, in the forming of the pixel circuit layer on the substrate (S100), transistors T_SP may be patterned on the substrate SUB to form the pixel circuit layer PCL.

According to an embodiment, a conductive layer and an insulating layer on the substrate SUB may be formed by general processes for manufacturing semiconductor devices. For example, the conductive layer or the insulating layer on the substrate SUB may be formed by a photolithography process, etched by various methods (wet etching, dry etching, or the like), and deposited by various methods (sputtering, chemical vapor deposition, or the like). The present disclosure is not necessarily limited to specific examples.

Referring to FIGS. 12 to 14, in the forming of the light emitting element layer on the pixel circuit layer (S200), the forming of the planarization layer (S220) may be performed.

In this step (S220), the planarization layer PLNL may reduce a step difference caused by the layers below.

Referring to FIGS. 12 to 14, in the forming of the light emitting element layer on the pixel circuit layer (S200), the forming of the anode electrode (S230) may be performed.

In this step (S230), the first and second anode electrodes AE1 and AE2 may be patterned to form the first and second sub-pixels SP1 and SP2. In addition, the first and second contact portions CNT1 and CNT2 penetrating the planarization layer PLNL may be formed, and the first and second anode electrodes AE1 and AE2 may be electrically connected to circuit elements of the pixel circuit layer PCL.

Referring to FIGS. 12 to 14, in the forming of the light emitting element layer on the pixel circuit layer (S200), the forming of the pixel defining layer (S240) may be performed.

In this step (S240), the pixel defining layer PDL may be patterned to cover an area between the first and second anode electrodes AE1 and AE2. According to an embodiment, the pixel defining layer PDL may be patterned to have a relatively narrow width PGAP. At least a portion of the pixel defining layer PDL may be disposed on the planarization layer PLNL.

Referring to FIGS. 12, 13, and 15, in the forming of the light emitting element layer on the pixel circuit layer (S200), the forming of the trench (S250) may be performed.

In this step (S250), within the boundary area BDA, at least a portion of each of the pixel defining layer PDL and the planarization layer PLNL may be removed, and the trench TRCH may be formed.

Referring to FIGS. 12, 13, and 16 to 19, in the forming of the light emitting element layer on the pixel circuit layer (S200), the forming of the light emitting structure (S260) may be performed.

In this step (S260), the light emitting structure EMS may be formed (for example, deposited), and at least a portion of the light emitting structure EMS may be discontinued or bent by the trench TRCH. In addition, at least a portion of the light emitting structure EMS may be provided within the trench TRCH, and the intermediate light emitting structure EMS_M may be formed.

Referring to FIGS. 12, 13, and 17, in the forming of the light emitting element layer on the pixel circuit layer (S200), the forming of the intermediate connection layer (S270) may be performed.

In this step (S270), within the boundary area BDA, the intermediate connection layer MCL may be patterned to overlap the intermediate light emitting structure EMS_M in a plan view. Accordingly, the intermediate connection layer MCL may connect the first light emitting structure EMS1 of the first sub-pixel SP1 and the second light emitting structure EMS2 of the second sub-pixel SP2.

In this step (S270), the intermediate connection layer MCL may be patterned using a fine silicon mask MAS including silicon. When patterning the intermediate connection layer MCL using the fine silicon mask MAS, the material can be deposited at a relatively high angle of incidence. For example, in a deposition process using the fine silicon mask MAS, an angle of incidence at which the material is deposited may be 80 degrees or more (for example, 80 to 90 degrees). In this case, a range of deposition shadow can be reduced. In addition, the size of a deposition opening DOP formed in the fine silicon mask MAS can be generally finely defined, and the intermediate connection layer MCL may be patterned in detail in some areas of the pixel defining layer PDL having a relatively narrow width PGAP. According to an embodiment, the width OWD of the deposition opening DOP may be 0.2 μm to 0.8 μm measured on a major surface plane of the fine silicon mask MAS. For example, the width OWD of the deposition opening DOP may be about 0.5 μm. That is, as the intermediate connection layer MCL according to the embodiment is manufactured using the fine silicon mask, the width PGAP of the pixel defining layer PDL can be reduced, and the display device 100 having high resolution characteristics can be provided.

However, the present disclosure is not necessarily limited thereto. For example, the intermediate connection layer MCL may be patterned using another type of mask, such as a fine metal mask.

According to an embodiment, a deposition process for forming the intermediate connection layer MCL may be performed using a deposition material provided from a deposition source. According to an embodiment, the deposition source may be implemented in various ways. For example, the deposition source may be a point-type source that is fixed at a specific location and sequentially provides the deposition material to a deposition target substrate. Alternatively, the deposition source may be a line-type deposition source that moves in a scanning manner and sequentially provides the deposition material to a line-shaped range of a deposition target substrate. According to an embodiment, when the deposition source is a point-type source, more detailed sub-pixel SP design can be possible, and more process margin can be secured in the processes of forming the intermediate connection layer MCL and the pixel defining layer PDL.

According to an embodiment, the plurality of intermediate connection layers MCL may be formed within the display area DA. According to an embodiment, the intermediate connection layers MCL may be patterned in the same process (for example, simultaneously). Alternatively, according to an embodiment, the intermediate connection layers MCL may each be formed through a plurality of processes. For example, referring to FIGS. 18 and 19, some of the intermediate connection layers MCL may be patterned using a fine silicon mask MAS at a first position in a first time period. Thereafter, other intermediate connection layers MCL may be patterned using the fine silicon mask MAS moved (or shifted) from the first position to a second position in a second time period after the first time period.

Referring to FIGS. 12, 13, and 20, in the forming of the light emitting element layer on the pixel circuit layer (S200), the forming of the cathode electrode (S280) may be performed.

In this step (S280), the cathode electrode CE may be deposited on an entire surface of the display area DA. The cathode electrode CE may cover the light emitting structures EMS and may cover the intermediate connection layer MCL. Since the intermediate connection layer MCL reduces a step difference caused by the layers below, the cathode electrode CE can be appropriately patterned without being discontinued at the boundary area BDA.

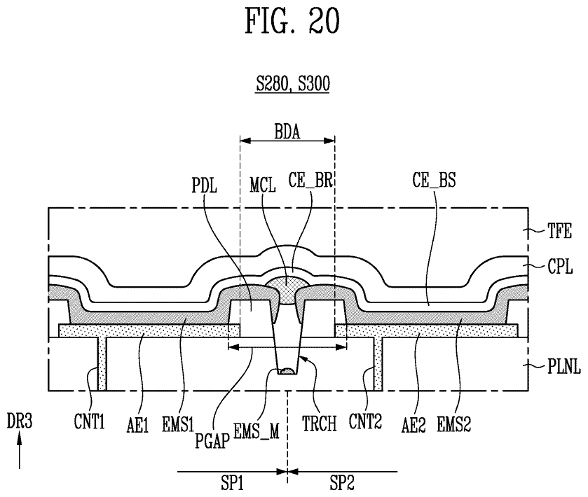

Referring to FIGS. 12 and 20, in the forming of the capping layer and the encapsulation layer on the light emitting element layer (S300), the capping layer CPL and the encapsulation layer TFE may be formed on the cathode electrode CE and the intermediate connection layer MCL.

In this step (S300), the capping layer CPL and the encapsulation layer TFE may be disposed, and the light emitting element layer LDL may be appropriately protected.

Referring to FIG. 12 in conjunction with FIG. 8, in the forming of the optical functional layer on the encapsulation layer (S400), the optical functional layer OFL including the color filters CF1 to CF3 and the lens array LA may be formed.

Thereafter, according to an embodiment, the overcoat layer OC, the cover window CW, and/or the like may be provided, and the display device 100 according to the embodiments may be provided.

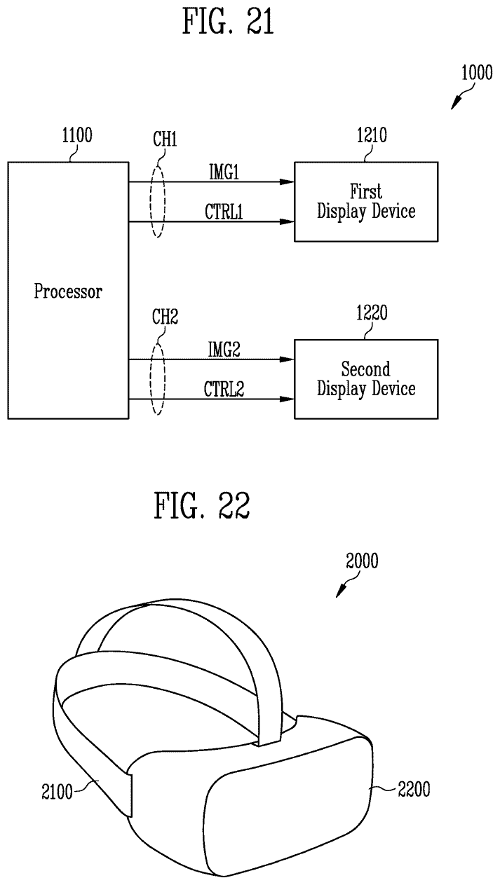

FIG. 21 is a block diagram illustrating an embodiment of a display system.

Referring to FIG. 21, a display system 1000 may include a processor 1100 and one or more display devices 1210 and 1220.

The processor 1100 may perform various tasks and calculations. In some embodiments, the processor 1100 may include an application processor, a graphics processor, a microprocessor, a central processing unit (“CPU”), and/or the like. The processor 1100 may be connected to and control other components of the display system 1000 through a bus system.

In FIG. 21, the display system 1000 is shown as including first and second display devices 1210 and 1220. The processor 1100 may be connected to the first display device 1210 through a first channel CH1 and to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1.

The display system 1000 may include a computing system that provides an image display function, such as a portable computer, a mobile phone, a smart phone, a tablet personal computer, a smart watch, a watch phone, a portable multimedia player (“PMP”), a navigation, and an ultra mobile personal computer (“UMPC”). In addition, the display system 1000 may include at least one of a head-mounted display (HMD) device, a virtual reality (VR) device, a mixed reality (MR) device, and an augmented reality (AR) device.

FIG. 22 is a perspective view illustrating an application example of the display system of FIG. 21.

Referring to FIG. 22, the display system 1000 of FIG. 21 may be applied to a head-mounted display device 2000. The head-mounted display device 2000 may be a wearable electronic device that can be worn on a user's head.

The head-mounted display device 2000 may include a head mounting band 2100 and a display device storage case 2200. The head mounting band 2100 may be connected to the display device storage case 2200. The head mounting band 2100 may include a horizontal band and/or a vertical band for fixing the head-mounted display device 2000 to the user's head. The horizontal band may be configured to surround the side of the user's head, and the vertical band may be configured to surround the top of the user's head. However, embodiments of the present disclosure are not limited thereto. For another example, the head mounting band 2100 may be implemented in the form of glasses frames, helmets, or the like.

The display device storage case 2200 may accommodate the first and second display devices 1210 and 1220 of FIG. 21. The display device storage case 2200 may further accommodate the processor 1100 of FIG. 21.

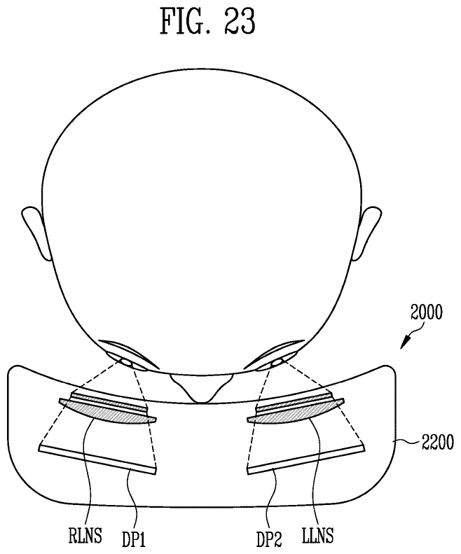

FIG. 23 is a diagram illustrating the head-mounted display device worn by a user of FIG. 22.

Referring to FIG. 23, within the head-mounted display device 2000, a first display panel DP1 of the first display device 1210 and a second display panel DP2 of the second display device 1220 may be disposed. The head-mounted display device 2000 may further include one or more lenses LLNS and RLNS.

Within the display device storage case 2200, a right eye lens RLNS may be disposed between the first display panel DP1 and the user's right eye. Within the display device storage case 2200, a left eye lens LLNS may be disposed between the second display panel DP2 and the user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function to adjust the viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function to adjust the viewing distance between the second display panel DP2 and the user's left eye.

In some embodiments, each of the right eye lens RLNS and the left eye lens LLNS may include an optical lens having a pancake-shaped cross section. In some embodiments, each of the right eye lens RLNS and the left eye lens LLNS may include a multi-channel lens including sub-regions with different optical properties. In this case, each display panel may output images corresponding to the sub-regions of the multi-channel lens, and the output images may pass through corresponding sub-regions and may be displayed to the user.

According to the embodiments of the present disclosure, a display device in which the risk of leakage current can be effectively reduce and a method of manufacturing the same can be provided.

An aspect of the present disclosure is to provide a display device capable of having high resolution and excellent display quality, and a method of manufacturing the same.

Another aspect of the present disclosure is to provide a display device that can secure a process margin, and a method of manufacturing the same.

As described above, the optimal embodiments of the present disclosure have been disclosed through the detailed description and the drawings. However, those skilled in the art or those of ordinary skill in the art will appreciate that various modifications and changes are possible without departing from the spirit and technical scope of the present disclosure as set forth in the claims below.

Therefore, the technical protection scope of the present disclosure is not limited to the detailed description described in the specification but should be determined by the appended claims.

What is claimed is:

1. A display device including sub-pixels including a first sub-pixel and a second sub-pixel adjacent to each other, comprising:
a pixel circuit layer including a pixel circuit on a substrate; and
a light emitting element layer disposed on the pixel circuit layer,
wherein the light emitting element layer includes:
a planarization layer;
an anode electrode disposed on the planarization layer;
a pixel defining layer, at least a portion of which is disposed on the anode electrode;
a trench penetrating the pixel defining layer and defined in at least a portion of the planarization layer;
a light emitting structure disposed over the first sub-pixel and the second sub-pixel, and at least a portion of which is disposed on a portion of the anode electrode exposed by the pixel defining layer, wherein the light emitting structure includes a first light emitting structure forming the first sub-pixel and a second light emitting structure forming the second sub-pixel;
an intermediate light emitting structure disposed within the trench at a boundary area between the anode electrode of the first sub-pixel and the anode electrode of the second sub-pixel and including a same material as the light emitting structure;
an intermediate connection layer disposed in the boundary area between the first sub-pixel and the second sub-pixel and connecting the first light emitting structure and the second light emitting structure; and
a cathode electrode disposed across the first sub-pixel and the second sub-pixel, and at least a portion of which is disposed on the intermediate connection layer,
wherein the intermediate light emitting structure and the intermediate connection layer are physically spaced apart from each other.

2. The display device of claim 1, wherein a void is formed between the intermediate light emitting structure and the intermediate connection layer.

3. The display device of claim 1, wherein the intermediate light emitting structure is provided in plurality,
wherein the trench is provided in plurality, and
wherein a total number of the plurality of intermediate light emitting structures and a total number of the plurality of trenches are the same.

4. The display device of claim 1, wherein the intermediate connection layer is provided in plurality, and
wherein the plurality of intermediate connection layers are disposed to be spaced apart from each other at edges of the sub-pixels.

5. The display device of claim 4, wherein each of the sub-pixels has a polygonal shape in a plan view, and
wherein the plurality of intermediate connection layers are disposed at vertices of the polygonal shape.

6. The display device of claim 1, wherein a width of a portion of the pixel defining layer between adjacent emission areas is 0.5 micrometers (μm) to 3.5 μm.

7. The display device of claim 1, wherein the light emitting structure includes a common layer commonly included in each of the first sub-pixel and the second sub-pixel, and
wherein the common layer is discontinued by the trench.

8. The display device of claim 7, wherein a thickness of the trench is greater than half a thickness of the light emitting structure, and
wherein a width of the trench is greater than ¼ of the thickness of the light emitting structure.

9. The display device of claim 7, wherein a side surface of the trench form an included angle of 60 to 90 degrees with respect to a plane on which a major surface of the substrate is disposed.

10. The display device of claim 1, further comprising:
a capping layer disposed across the first sub-pixel and the second sub-pixel and disposed on the cathode electrode; and
an encapsulation layer disposed on the capping layer,
wherein the capping layer and the encapsulation layer overlap the intermediate connection layer and the intermediate light emitting structure in a plan view.

11. The display device of claim 10, wherein the capping layer and the intermediate connection layer are directly adjacent to each other.

12. The display device of claim 1, wherein the intermediate connection layer includes an organic material having electron transport properties.

13. The display device of claim 1, wherein the substrate includes a silicon substrate.

14. A method of manufacturing a display device including sub-pixels including a first sub-pixel and a second sub-pixel adjacent to each other, comprising:
forming a pixel circuit layer including a pixel circuit on a substrate; and
forming a light emitting element layer on the pixel circuit layer,
wherein the forming of the light emitting element layer includes:
forming a planarization layer;
forming an anode electrode on the planarization layer;
forming a pixel defining layer, at least a portion of which covers the anode electrode;
forming a trench penetrating the pixel defining layer and defined in at least a portion of the planarization layer;
forming a light emitting structure over the first sub-pixel and the second sub-pixel;
forming an intermediate connection layer disposed in a boundary area between the anode electrode of the first sub-pixel and the anode electrode of the second sub-pixel; and
forming a cathode electrode over the first sub-pixel and the second sub-pixel,
wherein the forming of the intermediate connection layer includes patterning the intermediate connection layer using a fine silicon mask.

15. The method of claim 14, wherein in the forming of the light emitting structure, at least a portion of the light emitting structure is discontinued by the trench.

16. The method of claim 14, wherein the forming of the light emitting structure includes forming an intermediate light emitting structure disposed within the trench.

17. The method of claim 16, wherein the light emitting structure includes a first light emitting structure forming the first sub-pixel and a second light emitting structure forming the second sub-pixel, and
wherein the forming of the intermediate connection layer includes:
patterning the intermediate connection layer to overlap the intermediate light emitting structure in a plan view; and
connecting the first light emitting structure and the second light emitting structure by the intermediate connection layer.

18. The method of claim 14, wherein the fine silicon mask defines a deposition opening therein, and
wherein a width of the deposition opening is 0.2 μm to 0.8 μm.

19. The method of claim 14, wherein the patterning of the intermediate connection layer includes patterning a plurality of intermediate connection layers, and
wherein the plurality of intermediate connection layers are patterned simultaneously.

20. The method of claim 14, wherein the patterning of the intermediate connection layer includes patterning a plurality of intermediate connection layers, and
wherein some of the plurality of intermediate connection layers are patterned in a first time period, and other intermediate connection layers of the plurality of intermediate connection layers are patterned in a second time period after the first time period.
